(19) United States
(12) Patent Application Publication
(10) Pub. No.: US 2025/0085351 A1
(43) Pub. Date: Mar. 13, 2025

(54) VEHICLE BATTERY MONITORING SYSTEM

(71) Applicant: GM Global Technology Operations LLC, Detroit, MI (US)

(72) Inventors: Benjamin Tran, Royal Oak, MI (US); Matthew Edward Gilbert-Eyres, Rochester Hills, MI (US); James Doherty, Detroit, MI (US); Kevin W. Owens, Sterling Heights, MI (US)

(73) Assignee: GM Global Technology Operations LLC, Detroit, MI (US)

(21) Appl. No.: 18/465,465

(22) Filed: Sep. 12, 2023

(51) Int. Cl. G01R 31/367; B60L 3/12; B60L 58/10; G01C 21/34; G01R 31/371; G01R 31/382

(52) U.S. Cl. CPC G01R 31/367; B60L 3/12; B60L 58/10; G01C 21/3469; G01R 31/371; G01R 31/382; B60L 2240/60

(57) ABSTRACT

A battery monitoring system includes a vehicle processor storing battery data and a user device communicatively coupled with the vehicle processor. The user device includes data processing hardware that stores a weather application, a navigation application, and a battery monitoring application. The battery monitoring application is configured to receive the battery data from the vehicle processor and weather data from the weather application. The battery monitoring application is also configured to present a user with battery efficiency options based on the battery data and the weather data.

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against present disclosure.

The present disclosure relates generally to a vehicle battery monitoring system.

Electric vehicles utilize specialized charging stations that are being increasingly integrated into service stations. Most electric vehicles present the driver with a range available before charging is suggested. The available range may be affected by the efficiency of the battery during operation. Often times, the battery efficiency may be reduced as a result of weather conditions and traffic conditions. As both weather conditions and traffic conditions are relatively unknown prior to departure, the driver often relies on monitoring the battery range to identify when to stop and charge the battery.

It is also common that the driver may utilize a navigation system to create a route to a destination. The route generated by the navigation system is typically the fastest route from the driver's departure location to the destination. Similarly, a driver may utilize a weather system to monitor weather during travel or may identify weather conditions at the destination location. While navigation systems and weather systems provide data relating to navigation and weather, respectively, these systems are typically separate from any battery data from the vehicle.

### SUMMARY

In some aspects, a battery monitoring system for a vehicle includes a vehicle processor that stores battery data including battery capacity and battery range. The battery monitoring system also includes a user device that is communicatively coupled with the vehicle processor and includes data processing hardware. The data processing hardware stores a weather application and a battery monitoring application that is configured to receive the battery data from the vehicle processor and weather data from the weather application. A server is communicatively coupled to the vehicle processor and the user device. The server is configured to monitor battery efficiency data from one or more third-party processors. The server is also configured to transmit the battery efficiency data to the user device, and the battery monitoring application is configured to present a user with battery predictions based on the battery data and the battery efficiency data.

In some examples, the vehicle processor may store ambient data from ambient controls of the vehicle, and the battery monitoring application may be configured to adjust the battery predictions based on the ambient data. In other examples, the user device may include a navigation application that is configured to display a route. The battery monitoring application may be configured to communicate with the navigation application and to present the battery range along the route. The server may be configured to identify one or more battery inefficiencies from the one or more third-party processors along the route. Optionally, the battery monitoring application may be configured to determine an alternate route in response to the one or more identified battery inefficiencies. The alternate route may be an efficiency route. In some instances, the battery monitoring application may be configured to predict a battery efficiency for the vehicle based on the weather data.

In another aspect, a battery monitoring system includes a vehicle processor storing battery data and a user device communicatively coupled with the vehicle processor. The user device includes data processing hardware that stores a weather application, a navigation application, and a battery monitoring application. The battery monitoring application is configured to receive the battery data from the vehicle processor and weather data from the weather application. The battery monitoring application is also configured to present a user with battery efficiency options based on the battery data and the weather data.

In some configurations, the battery efficiency options may include one or more of an alternate travel time, an alternate route, and efficient driving patterns. The efficient driving patterns may include recommendations for increased battery efficiency. In some examples, the battery monitoring application may be configured to determine the alternate route and the alternate travel time in response to navigation data from the navigation application. The battery monitoring application may be configured to determine the battery efficiency options based on the battery data, the weather data, and the navigation data. The navigation data may include a route and traffic data, and the battery monitoring application may be configured to determine an efficiency of the route based on at least one of the weather data and the traffic data. In some examples, the battery monitoring system may also include a server that may be configured to identify third-party processors along the route and may be configured to transmit third-party efficiency data to the battery monitoring application.

In yet another aspect, a vehicle battery monitoring system includes a vehicle processor storing battery data and a user device communicatively coupled with the vehicle processor. The user device includes data processing hardware that stores a navigation application and a battery monitoring application. The battery monitoring application is configured to receive the battery data from the vehicle processor and navigation data from the navigation application. A server is communicatively coupled to the user device and is configured to receive the navigation data and to monitor battery efficiency data from one or more third-party processors based on the navigation data. The server is also configured to transmit the battery efficiency data to the user device, and the battery monitoring application is configured to present a user with revised efficiency options based on the battery data and the battery efficiency data.

In some examples, the user device may include a weather application that may include weather data, and the battery monitoring application may be configured to determine a battery efficiency option in response to the weather data. The battery efficiency option may include an alternate departure time. In some aspects, the battery monitoring application may be configured to identify a first route and a second route based on the navigation data and the battery data. The battery monitoring application may be configured to compare the battery efficiency data from the server with each of the first route and the second route. Optionally, the battery monitoring application may be configured to present one of the first route and the second route as an efficiency route in response to the battery efficiency data.

### BRIEF DESCRIPTION OF THE DRAWINGS

The drawings described herein are for illustrative purposes only of selected configurations and are not intended to limit the scope of the present disclosure.

FIG. 1 is a perspective view of a vehicle having a vehicle processor in communication with a user device according to the present disclosure;

FIG. 2 is a functional block diagram of a battery monitoring system according to the present disclosure:

FIG. 3 is a schematic view of a battery monitoring application according to the present disclosure:

FIG. 4 is a schematic view of a navigation application of a user device according to the present disclosure:

FIG. 5 is a schematic view of a route planned on a navigation application according to the present disclosure:

FIG. 6 is a schematic view of a battery monitoring application according to the present disclosure presenting an efficiency route:

FIG. 7 is a schematic view of a notification presented on a battery monitoring application according to the present disclosure:

FIG. 8 is an example flow diagram of a battery monitoring application according to the present disclosure; and

FIG. 9 is another example flow diagram of a battery monitoring application according to the present disclosure.

Corresponding reference numerals indicate corresponding parts throughout the drawings.

### DETAILED DESCRIPTION

Example configurations will now be described more fully with reference to the accompanying drawings. Example configurations are provided so that this disclosure will be thorough, and will fully convey the scope of the disclosure to those of ordinary skill in the art. Specific details are set forth such as examples of specific components, devices, and methods, to provide a thorough understanding of configurations of the present disclosure. It will be apparent to those of ordinary skill in the art that specific details need not be employed, that example configurations may be embodied in many different forms, and that the specific details and the example configurations should not be construed to limit the scope of the disclosure.

The terminology used herein is for the purpose of describing particular exemplary configurations only and is not intended to be limiting. As used herein, the singular articles “a,” “an,” and “the” may be intended to include the plural forms as well, unless the context clearly indicates otherwise. The terms “comprises,” “comprising,” “including,” and “having,” are inclusive and therefore specify the presence of features, steps, operations, elements, and/or components, but do not preclude the presence or addition of one or more other features, steps, operations, elements, components, and/or groups thereof. The method steps, processes, and operations described herein are not to be construed as necessarily requiring their performance in the particular order discussed or illustrated, unless specifically identified as an order of performance. Additional or alternative steps may be employed.

When an element or layer is referred to as being “on,” “engaged to,” “connected to.” “attached to,” or “coupled to” another element or layer, it may be directly on, engaged, connected, attached, or coupled to the other element or layer, or intervening elements or layers may be present. In contrast, when an element is referred to as being “directly on.” “directly engaged to.” “directly connected to,” “directly attached to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The terms first, second, third, etc. may be used herein to describe various elements, components, regions, layers and/or sections. These elements, components, regions, layers and/or sections should not be limited by these terms. These terms may be only used to distinguish one element, component, region, layer or section from another region, layer or section. Terms such as “first.” “second,” and other numerical terms do not imply a sequence or order unless clearly indicated by the context. Thus, a first element, component, region, layer or section discussed below could be termed a second element, component, region, layer or section without departing from the teachings of the example configurations.

In this application, including the definitions below; the term module may be replaced with the term circuit. The term module may refer to, be part of, or include an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor (shared, dedicated, or group) that executes code; memory (shared, dedicated, or group) that stores code executed by a processor; other suitable hardware components that provide the described functionality; or a combination of some or all of the above, such as in a system-on-chip.

The term code, as used above, may include software, firmware, and/or microcode, and may refer to programs, routines, functions, classes, and/or objects. The term shared processor encompasses a single processor that executes some or all code from multiple modules. The term group processor encompasses a processor that, in combination with additional processors, executes some or all code from one or more modules. The term shared memory encompasses a single memory that stores some or all code from multiple modules. The term group memory encompasses a memory that, in combination with additional memories, stores some or all code from one or more modules. The term memory may be a subset of the term computer-readable medium. The term computer-readable medium does not encompass transitory electrical and electromagnetic signals propagating through a medium, and may therefore be considered tangible and non-transitory memory. Non-limiting examples of a non-transitory memory include a tangible computer readable medium including a nonvolatile memory, magnetic storage, and optical storage.

The apparatuses and methods described in this application may be partially or fully implemented by one or more computer programs executed by one or more processors. The computer programs include processor-executable instructions that are stored on at least one non-transitory tangible computer readable medium. The computer programs may also include and/or rely on stored data.

A software application (i.e., a software resource) may refer to computer software that causes a computing device to perform a task. In some examples, a software application may be referred to as an “application,” an “app,” or a “program.” Example applications include, but are not limited to, system diagnostic applications, system management applications, system maintenance applications, word processing applications, spreadsheet applications, messaging applications, media streaming applications, social networking applications, and gaming applications.

The non-transitory memory may be physical devices used to store programs (e.g., sequences of instructions) or data (e.g., program state information) on a temporary or permanent basis for use by a computing device. The non-transitory memory may be volatile and/or non-volatile addressable semiconductor memory. Examples of non-volatile memory include, but are not limited to, flash memory and read-only memory (ROM)/programmable read-only memory (PROM)/erasable programmable read-only memory (EPROM)/electronically erasable programmable read-only memory (EEPROM) (e.g., typically used for firmware, such as boot programs). Examples of volatile memory include, but are not limited to, random access memory (RAM), dynamic random access memory (DRAM), static random access memory (SRAM), phase change memory (PCM) as well as disks or tapes.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” and “computer-readable medium” refer to any computer program product, non-transitory computer readable medium, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

Various implementations of the systems and techniques described herein can be realized in digital electronic and/or optical circuitry, integrated circuitry, specially designed ASICS (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

The processes and logic flows described in this specification can be performed by one or more programmable processors, also referred to as data processing hardware, executing one or more computer programs to perform functions by operating on input data and generating output. The processes and logic flows can also be performed by special purpose logic circuitry, e.g., an FPGA (field programmable gate array) or an ASIC (application specific integrated circuit). Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks: magneto optical disks; and CD ROM and DVD-ROM disks. The processor and the memory can be supplemented by, or incorporated in, special purpose logic circuitry.

To provide for interaction with a user, one or more aspects of the disclosure can be implemented on a computer having a display device, e.g., a CRT (cathode ray tube), LCD (liquid crystal display) monitor, or touch screen for displaying information to the user and optionally a keyboard and a pointing device, e.g., a mouse or a trackball, by which the user can provide input to the computer. Other kinds of devices can be used to provide interaction with a user as well: for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

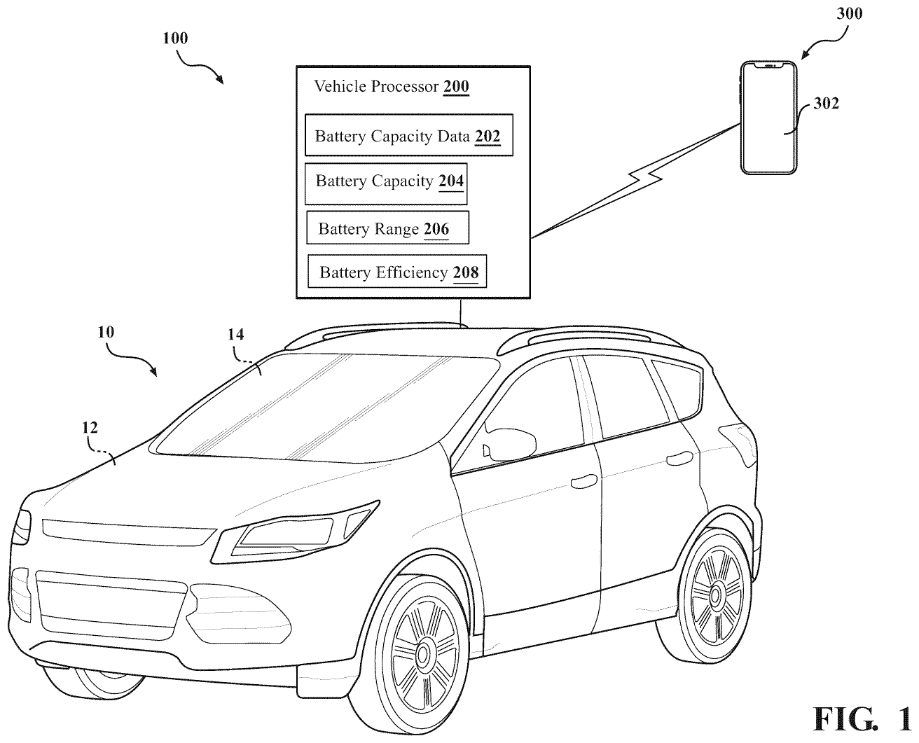

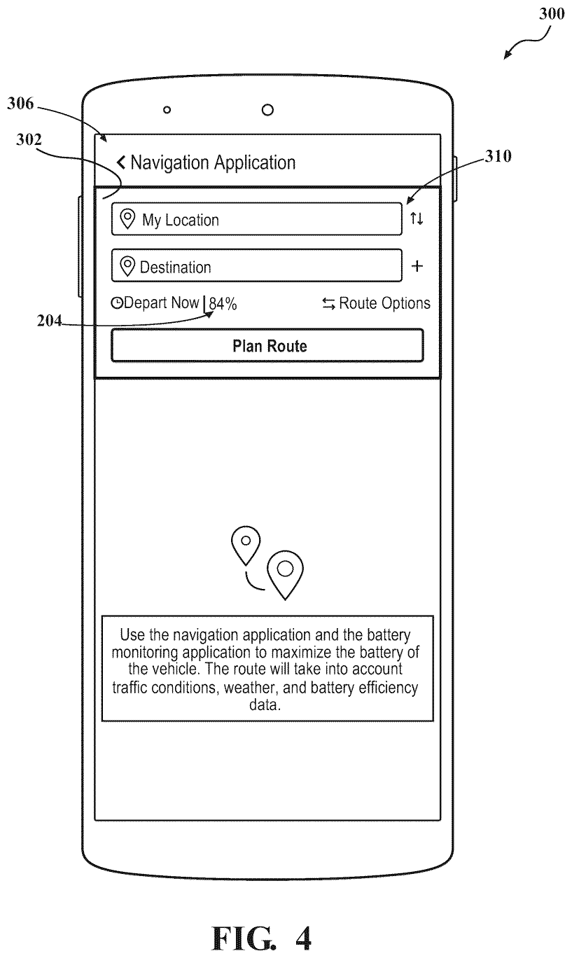

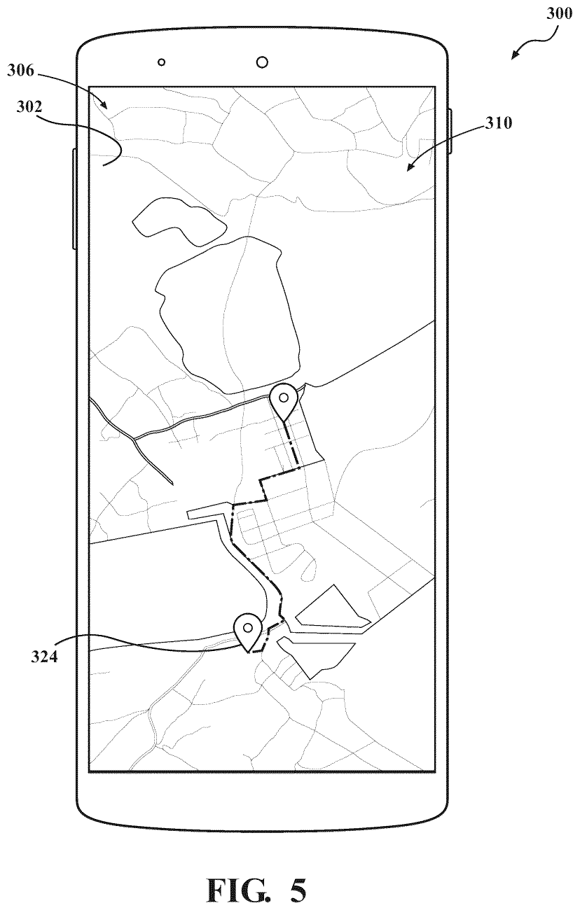

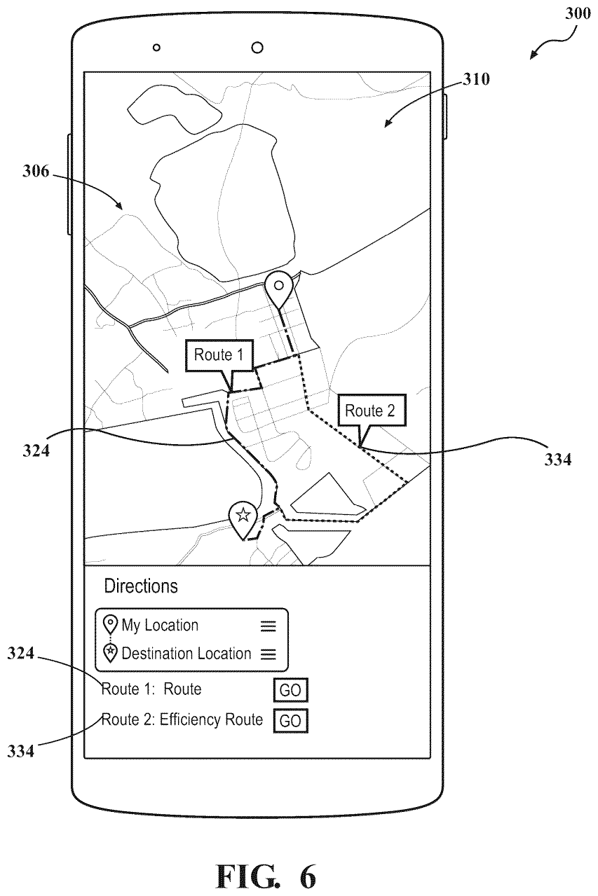

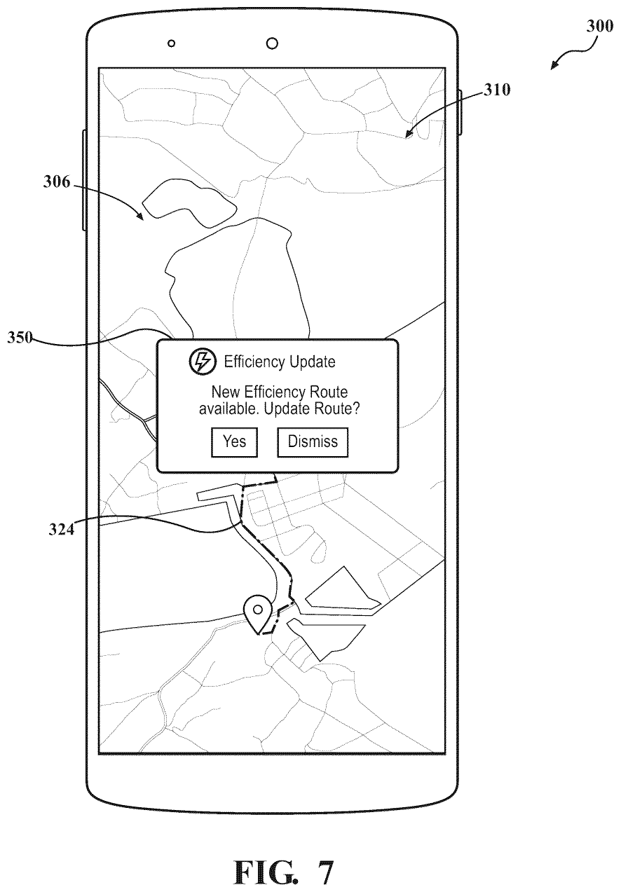

Referring to FIGS. 1-9, a battery monitoring system 100 for a vehicle 10 includes a vehicle processor 200 in communication with a user device 300. The monitoring system 100 may also include a server 400, described in more detail below, that is communicatively coupled with one or both of the vehicle processor 200 and the user device 300. The vehicle 10, described below, is contemplated to be an electric vehicle (EV) with autonomous or semi-autonomous capabilities. Additionally or alternatively, the vehicle 10 may be a hybrid vehicle incorporating both EV and internal combustion engine (ICE) components and capabilities. Accordingly, the vehicle 10 is equipped with a battery 12 to provide, at least in part, propulsion assistance for the vehicle 10. The vehicle processor 200 stores battery data 202 of the battery 12 of the vehicle 10.

The battery data 202 includes a battery capacity 204 and a battery range 206 of the battery 12. It is also contemplated that the battery data 202 may also include a battery efficiency 208. However, in some examples, the battery efficiency 208 may be predicted or otherwise determined by the user device 300, described below. The battery capacity 204 generally pertains to the operational capacity of the battery 12, while the battery range 206 pertains to an available distance that may be covered based on the current battery capacity 204. Thus, the vehicle processor 200 may utilize the battery capacity 204 to inform the battery range 206. Both the battery capacity 204 and the battery range 206 are collectively included as part of the battery data 202. For example, the vehicle processor 200 may communicate the battery capacity 204 and the battery range 206 with the user device 300 in the form of the battery data 202.

The battery efficiency 208 pertains to the operational efficiency of the battery 12. The efficiency of the battery 12 may be affected by various external factors including, but not limited to, weather, traffic patterns, road conditions, and driving patterns. The battery efficiency 208 may be identified, at least in part, by a change in the battery capacity 204 and the battery range 206 during operation of the vehicle 10. It is contemplated that the battery efficiency 208 may change throughout operation of the vehicle 10, such that the battery efficiency 208 may increase and decrease depending on the various external factors.

Referring to FIGS. 1-3, the vehicle processor 200 may also be configured to control and/or monitor the ambient environment within an interior cabin 14 of the vehicle 10. For example, the vehicle processor 200 may include ambient controls 210, which may be configured to collect ambient data 212 from within the interior cabin 14. The ambient controls 210 are configured to adjust a cooling and heating system of the vehicle 10. The ambient controls 210 may also include comfort settings within the vehicle 10, such as heated seating and/or massage features. The ambient data 212 may include selected temperatures, fan speeds, heated seat or massage selections, and/or directional output selection. As described herein, the vehicle processor 200 communicates the ambient data 212 with the user device 300, in combination with the battery data 202, as part of the battery monitoring system 100.

The vehicle processor 200 may further collect operational data 214 from the vehicle 10, which may include functional operations. For example, the operational data 214 may include activation of windshield wipers, windows, sunshades, sunroof, and/or mirrors of the vehicle 10. The operational data 214 may be utilized by the vehicle processor 200 to inform and update the battery data 202, such that some of the functional operations may utilize the battery 12 and potentially deplete the battery capacity 204. Thus, the vehicle processor 200 may collect the ambient data 212 and the operational data 214 to adjust the battery data 202 communicated with the user device 300. Further, the vehicle processor 200 may collect driving data 216 that may be communicated with the user device 300. The driving data 216 may inform the battery efficiency 208, such that the user device 300 may compare the battery data 202 with the driving data 216.

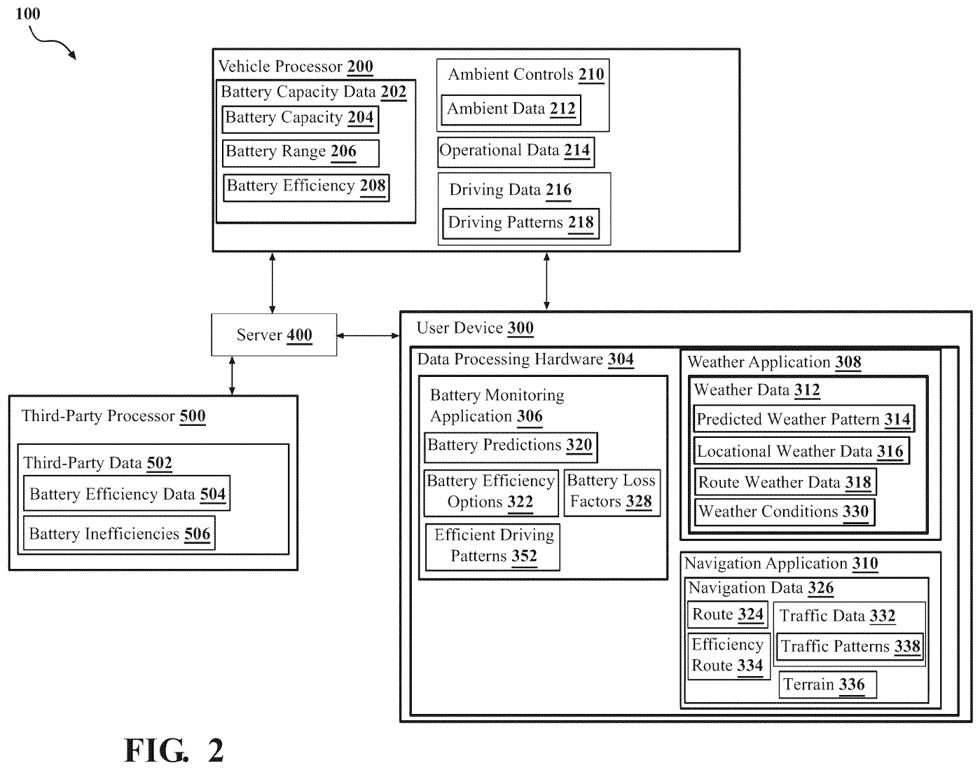

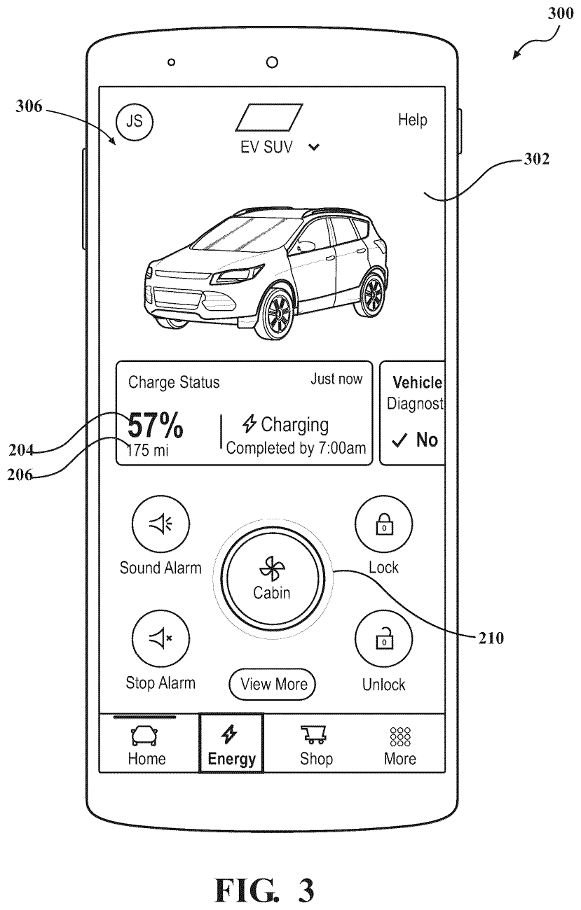

Referring to FIGS. 2-5, the user device 300 includes a display 302 and data processing hardware 304 that is configured to execute a battery monitoring application 306. The battery monitoring application 306 is configured to present the battery data 202 received from the vehicle processor 200 to an occupant of the vehicle 10. For example, the battery monitoring application 306 may present the current battery capacity 204 and the current battery range 206 on the display 302 of the user device 300. It is also contemplated that, as illustrated in FIG. 3, the occupant or user may adjust the ambient controls 210 via the battery monitoring application 306 and that the battery monitoring application 306 may display the driving data 216.

The user device 300 is also configured with a weather application 308 and a navigation application 310 each communicatively coupled with the battery monitoring application 306. The weather application 308 includes weather data 312 that includes predicted weather patterns 314, described below: The weather data 312 may include locational weather data 316 based on a current location of the vehicle 10 and route weather data 318. The battery monitoring application 306 is configured to utilize the weather data 312 in combination with the battery data 202 to identify various battery predictions 320 of the battery 12, described below: Additionally or alternatively, the battery monitoring application 306 utilizes the battery data 202 and the weather data 312 to present the user with battery efficiency options 322 that are based on the battery data 202 and the weather data 312.

The navigation application 310 is configured to provide a route 324 and collect navigation data 326. For example, the navigation application 310 may include a map that displays various aspects of a region including, but not limited to, terrain, road grade, and traffic conditions. The navigation application 310 and the weather application 308 may be configured to exchange data. For example, the weather application 308 may receive the route 324 from the navigation application 310 to collect the route weather data 318 along the planned route 324. The weather application 308 may then send the weather data 312 corresponding to the route 324 to one or both of the navigation application 310 and the battery monitoring application 306. As described herein, each of the weather application 308 and the navigation application 310 are configured to communicate and exchange data with the battery monitoring application 306.

With further reference to FIGS. 2-5, the server 400 is configured as a network and/or a cloud-based system that communicates with one or both of the vehicle processor 200 and the user device 300. The server 400 is also configured to communicate with third-party processors 500 to collect third-party data 502. For example, the third-party processors 500 may include, but are not limited to, vehicle processors along the route 324 input via the user device 300. Additionally or alternatively, the third-party processors 500 may include third-party user devices within vehicles along the route 320. It is generally contemplated that the third-party data 502 includes battery efficiency data 504 from the third-party processors 500. The battery efficiency data 504 is configured communicate to the server 400 a third-party battery efficiency of each respective vehicle battery traveling along the route 324. In some examples, the server 400 may also identify battery inefficiencies 506 along the route 324, which may be communicated with the battery monitoring application 306. While the battery monitoring application 306 of the user device 300 is described herein as evaluating the battery efficiency data 504, it is contemplated that the server 400 may also evaluate the battery efficiency data 504 in some examples.

The battery monitoring application 306 may identify aspects of the route 324 that may be affecting an efficiency of the third-party batteries based on the battery efficiency data 504. In some instances, the battery monitoring application 306 may identify battery loss factors 328 along the route 324 based on the battery efficiency data 504. The battery loss factors 328 may include weather conditions 330 including, but not limited to, temperature, wind, rain, humidity, snow, and/or ice along the route 324. For example, the battery monitoring application 306 may compare a location of the third-party processors 500 along the route 324 with the weather data 312 from the weather application 308. Based on the weather conditions 330 at the location and the battery efficiency data 504 along the route 324, the battery loss factors 328 may be predicted or otherwise identified by the battery monitoring application 306 using the weather data 312.

The weather conditions 330 may impact the efficiency of the battery 12 by reducing road traction, increasing resistance on the vehicle 10, or reducing the operational efficiency of the battery 12. For example, the battery 12 can be affected by the temperatures, such that the battery 12 may be less efficient in extreme hot or cold temperatures, which ultimately impact the battery range 206 of the vehicle 10. In other examples, strong headwinds can increase resistance on the vehicle 10 and may result in the battery 12 utilizing additional battery capacity 204 to maintain the set speed of the vehicle 10. The increased resistance may reduce overall battery efficiency 208 and, thus, the battery range 206 due to the compensation of the battery 12 against the potential headwind. In further examples, rain may increase drag on the vehicle 10 and decrease the battery efficiency 208, while utilization of windshield wipers and other electrical components, recorded as operational data 214, may also reduce the battery efficiency 208 of the battery 12. Other weather conditions 330, such as high humidity levels and/or snow or ice, may further reduce the overall battery efficiency 208 of the battery 12. The impact of the various weather conditions 330 may be evaluated by the battery monitoring application 306 by comparing the weather data 312 with the battery efficiency data 506.

Referring still to FIGS. 2-5, the battery loss factors 328 may also be determined based on the navigation data 326. The navigation data 326 is used to identify the battery loss factors 328. In determining the battery loss factors 328, the battery monitoring application 306 may compare the navigation data 326 and one or more of the battery efficiency data 504 and/or the battery inefficiencies 506 gathered from the third-party processors 500, traffic data 332, and/or information obtained from the navigation application 310. For example, the navigation application 310 may identify a slow traffic pattern and communicate the slow traffic pattern as the traffic data 332. The battery monitoring application 306 may update the route 324 based, in part, on the battery loss factors 328. As described below, the battery monitoring application 306 may receive a user input corresponding to a route 324 input into the navigation application 310, and the battery monitoring application 306 may determine an efficiency route 334 based on the battery loss factors 328, the weather data 312, the traffic data 332, and the efficiency data 504.

Referring now to FIGS. 2 and 4-7, an example navigation application 310 is illustrated with an input route 324. In some examples, the navigation application 310 may communicate the input route 324 with the battery monitoring application 306. The battery monitoring application 306, as mentioned above, is configured to compare the input route 324 with the battery efficiency data 504, the weather data 312, the navigation data 326, and the traffic data 332 to evaluate an efficiency of the input route 324.

In some instances, the battery monitoring application 306 may determine that the input route 324 includes inefficiencies and may propose the efficiency route 334 as an alternate route. The alternate route 334 may be referred to as the efficiency route 334, as the alternate route 334 is determined to be more efficient than the input route 324. Efficiency is determined by the battery monitoring application 306 based on the optimized operation of the battery 12 along a route, such that there are minimal battery loss factors 328. For example, the server 400 may identify one or more battery inefficiencies 506 based on the third-party data 502 received from the third-party processors 500 along the input route 324 and may communicate the battery inefficiencies 506 with the battery monitoring application 306. In response to the identified battery inefficiencies 506, the battery monitoring application 306 may determine the efficiency route 334. Thus, the battery monitoring application 306 may identify a first route 324 and a second route 324 and present one of the first route 324 and the second route 324 as the efficiency route 334 in response to the efficiency data 504.

With further reference to FIGS. 2 and 4-7, in determining the efficiency route 334, the battery monitoring application 306 evaluates the weather data 312 received from the weather application 308. In some examples, the battery monitoring application 306 is configured to determine a battery efficiency option 322 in response to the weather data 312. The battery efficiency option 322 may include, for example, an alternate departure time and/or alternate travel time to optimize an external temperature during travel. The battery monitoring application 306 may determine from the weather data 312 that an input departure time may reduce the overall battery capacity 204 and, thus, battery range 206. In response, the battery monitoring application 306 may recommend the alternate departure time and/or alternate travel time to occur at a time of day when the temperature may be optimized for travel. In other examples, the battery monitoring application 306 may identify weather conditions 330 along the input route 324 that may result in inefficiencies along the route 324 that may be avoided by the efficiency route 334. Thus, the battery monitoring application 306 may recommend the efficiency route 334 to maximize the battery efficiency based on, for example, the weather data 312.

For example, the battery monitoring application 306 evaluates the route weather data 318 for the input route 324 and compares the route weather data 318 with the predicted weather patterns 314 in the surrounding area. The battery monitoring application 306 may identify the alternate route 334 as avoiding the weather conditions 330 along the input route 324 and, therefore, avoiding potential battery loss factors 328. In some examples, the battery monitoring application 306 may display an icon or otherwise indicate the weather conditions associated with each respective route 324, 334 to provide a visual indication of the weather condition 330. The icon may assist the user in visualizing the differences between the routes 324, 334 in the event that the weather data 312 informs the alternate route 334.

The battery monitoring application 306 is also configured to evaluate the navigation data 326 received from the navigation application 310 in evaluating the input route 324. For example, the traffic data 332 along the input route 324 may indicate that traffic along the route 324 may result in inefficiencies when traveling along the route 324. In some examples, the navigation data 326 may include a terrain 336 along the route 324, which may affect the battery efficiency 208 during travel. For example, the terrain 336 may include a steep incline that may utilize a significant percentage of the battery capacity 204. Thus, the battery monitoring application 306 may identify the alternate route 334 to maximize the battery capacity 204 and the battery range 206. In the example of a steep incline, the alternate route 334 may avoid the steep incline and may utilize a more gradual terrain 336.

Once the battery monitoring application 306 identifies the alternate, efficiency route 334, the battery monitoring application 306 may issue a notification 350 indicating the availability of the efficiency route 334. It is also contemplated that the battery monitoring application 306 may identify the efficiency route 334 after the vehicle 10 is traveling along the input route 324. In this example, the battery monitoring application 306 issues the notification 350 alerting the user to the availability of the efficiency route 334 and providing the option to switch to the efficiency route 334.

As the vehicle 10 travels along the route 324, 334, the battery monitoring application 306 continuously receives and monitors the driving data 216 from the vehicle processor 200. The driving data 216 includes driving patterns 218 that include, but are not limited to, a rate of speed and brake usage. The battery monitoring application 306 may track and monitor the driving patterns 218 for a predetermined period of time. The battery monitoring application 306 may present efficient driving patterns 352. For example, the efficient driving patterns 352 may include recommendations for increased battery efficiency based on the driving patterns 350. Thus, the battery monitoring application 306 may present various battery efficiency options 322 including one or more of the alternate travel time, the alternate route 334, and the efficient driving patterns 352.

Each of the battery efficiency options 322 may be determined or otherwise based upon the battery data 202, the weather data 312, and the navigation data 326. In addition to presenting the recommendations for increased battery efficiency 208, the battery monitoring application 306 may also present the battery range 206 along the route 324. Thus, the user may continuously monitor the battery range 206 during operation of the vehicle 10 and may adjust the driving patterns 218 in response to changes to the battery range 206. It is contemplated that the battery monitoring application 306 may continuously and/or regularly update the battery range 206 to reflect real-time battery data 202.

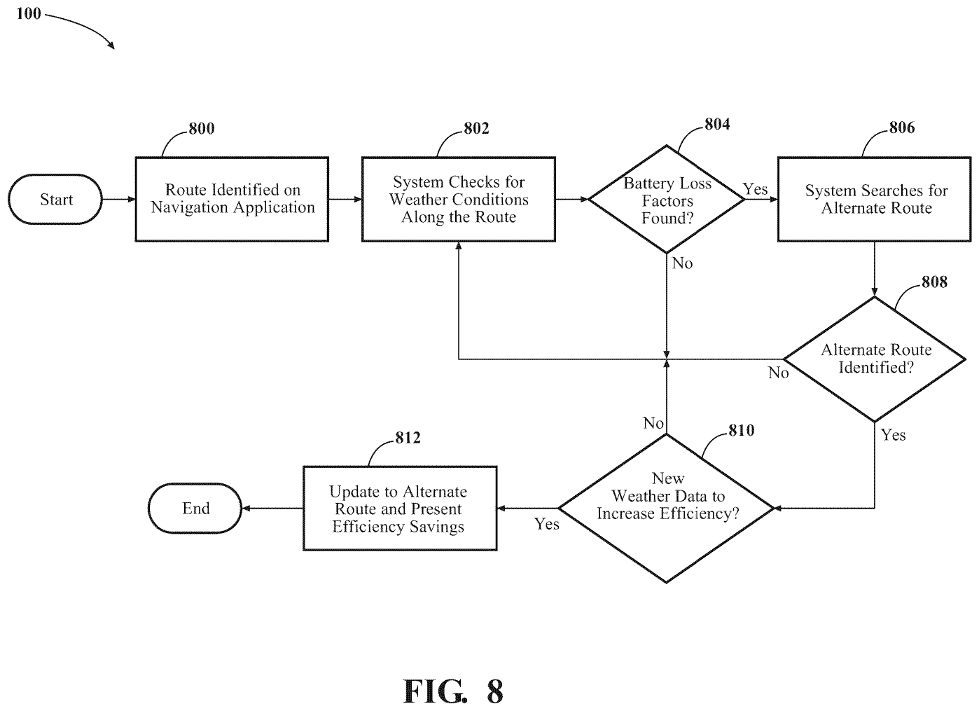

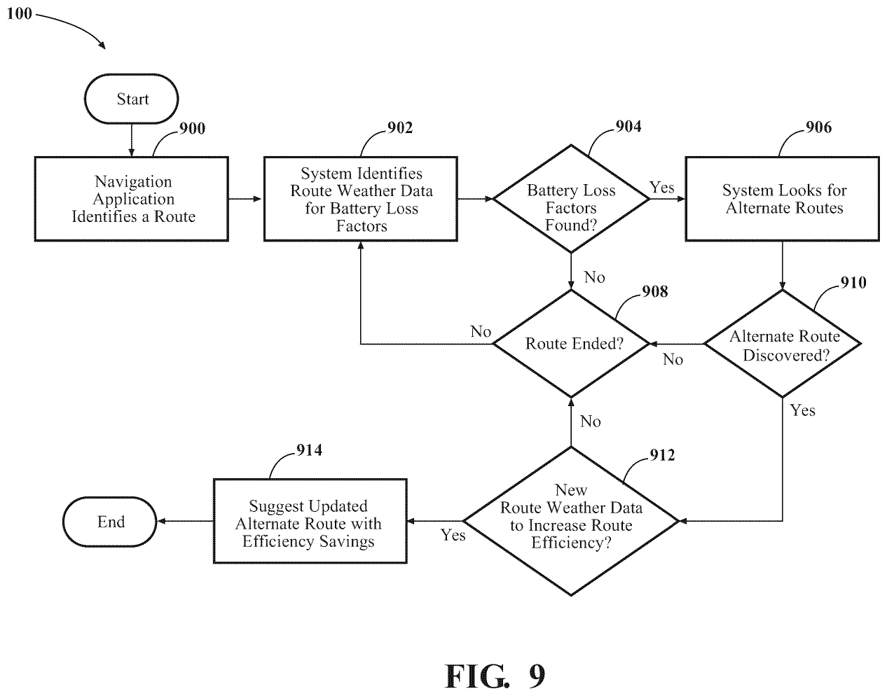

Referring now to FIGS. 1-8, an example flow diagram of operations of the battery monitoring system 100 is set forth in FIGS. 8 and 9. In an initial step, at 800, the user inputs a destination into the navigation application 310. Additionally or alternatively, the battery monitoring system 100 may detect the initiation of a route 324 based on communication with the vehicle processor 200 and the navigation application 310. The battery monitoring system 100, at 802, checks for weather conditions 330 along the route 324, and the battery monitoring system 100, at 804, identifies various inefficiencies or battery loss factors 328 along the route 324 based on, but not limited to, the weather data 312, the navigation data 326, the third-party data 502, and the battery data 202. If no inefficiencies are detected, then the battery monitoring system 100 returns to step 804. If inefficiencies are detected, then the battery monitoring system 100, at 806, searches for an alternate route 334 and/or alternate departure or travel times.

If an alternate route 334 is identified, the battery monitoring application 306, at 808, evaluates the weather data 312 to identify predicted weather patterns 314 that may increase the battery efficiency 208. If no predicted weather patterns 314 are detected, then the battery monitoring system 100 returns to step 804. If efficiency can be increased based on the alternate route 334 and the predicted weather patterns 314, then the battery monitoring application 306, at 810, may suggest the alternate route 334 including a new departure time. It is contemplated that in presenting the alternate route 334, the battery monitoring application 306 may also present a new estimated time of arrival as well as the efficiency savings associated with selecting the alternate route 334.

FIG. 9 illustrates a flow diagram of the battery monitoring system 100 identifying an alternate route 334 based on the navigation data 326. The navigation application 310, at 900, identifies a route 324 of the vehicle 10. It is contemplated that the route 324 may be input by the user or detected based on the operation of the vehicle 10. The battery monitoring system 100, at 902, identifies route weather data 318 to identify, at 904, efficiency or battery loss factors 328. If battery loss factors 328 are identified then, at 906, the battery monitoring application 306 identifies an alternate route 334 with a similar arrival time. If no battery loss factors 328 are identified, then, at 908, the battery monitoring application 306 determines whether the route 324 has ended. If the route has ended, then the battery monitoring application 306 may terminate the evaluation process. If the route has not ended, then the system 100 returns to step 902.

The battery monitoring application 306, at 910, determines whether an alternate route 334 was identified from step 906, and if the alternate route 334 is available, then, at 912, the battery monitoring application 306 identifies whether there is new route weather data 318 that may be utilized to increase the efficiency of the alternate route 334. If increased efficiencies are available, then the battery monitoring application 306, at 914, suggests a new efficiency route 334 to the user. The new efficiency route 334 may also present a new estimated time of arrival as well as the efficiency savings associated with selecting the alternate route 334.

Referring again to FIGS. 1-9, the battery monitoring application 306 is configured to receive the weather data 312 from the weather application 308, the navigation data 326 from the navigation application 310, and the third-party data 502 from the server 400. The third-party data 502 from the server 400 may inform or supplement the navigation data 326 and the route weather data 318. For example, the route weather data 318 may include the predicted weather patterns 314 along the route 324 and may include active route weather data 318. The battery monitoring application 306 may utilize the active route weather data 318, in combination with the predicted weather patterns 314, to potentially adjust, modify, or otherwise update the route 324. It is contemplated that the weather data 312, collectively, may inform or otherwise impact the efficiency of the battery 12 along the original route 324. It is also contemplated that the navigation data 326 may similarly inform the efficiency of the battery 12.

The battery monitoring application 306 may thus present the battery efficiency options 322 on the display 302. For example, the battery efficiency options 322 may include an alternate departure time and/or an alternate route 334, each of which may be configured to avoid the traffic patterns 338 and/or weather conditions 330 identified by the weather data 312. Thus, the battery monitoring system 100 may advantageously assist in monitoring the battery efficiency 208 relative to external factors. By comparison of the weather data 312, the navigation data 326, and third-party data 502, the battery monitoring application 306 may identify efficiency savings in a variety of ways. In some examples, among others, the battery monitoring application 306 may recommend adjusting driving patterns 218, taking alternate routes 334 to avoid battery loss factors 328, and/or adjusting a travel time.

A number of implementations have been described. Nevertheless, it will be understood that various modifications may be made without departing from the spirit and scope of the disclosure. Accordingly, other implementations are within the scope of the following claims.

The foregoing description has been provided for purposes of illustration and description. It is not intended to be exhaustive or to limit the disclosure. Individual elements or features of a particular configuration are generally not limited to that particular configuration, but, where applicable, are interchangeable and can be used in a selected configuration, even if not specifically shown or described. The same may also be varied in many ways. Such variations are not to be regarded as a departure from the disclosure, and all such modifications are intended to be included within the scope of the disclosure.

What is claimed is:

1. A battery monitoring system for a vehicle, the battery monitoring system comprising:
a vehicle processor storing battery data including battery capacity and battery range;
a user device communicatively coupled with the vehicle processor and including data processing hardware storing a weather application and a battery monitoring application configured to receive the battery data from the vehicle processor and weather data from the weather application; and
a server communicatively coupled to the vehicle processor and the user device and configured to monitor battery efficiency data from one or more third-party processors, the server configured to transmit the battery efficiency data to the user device and the battery monitoring application configured to present a user with battery predictions based on the battery data and the battery efficiency data.

2. The battery monitoring system of claim 1, wherein the vehicle processor stores ambient data from ambient controls of the vehicle and the battery monitoring application is configured to adjust the battery predictions based on the ambient data.

3. The battery monitoring system of claim 1, wherein the user device includes a navigation application configured to display a route, the battery monitoring application configured to communicate with the navigation application and to present the battery range along the route.

4. The battery monitoring system of claim 3, wherein the server is configured to identify one or more battery inefficiencies from the one or more third-party processors along the route.

5. The battery monitoring system of claim 4, wherein the battery monitoring application is configured to determine an alternate route in response to the one or more identified battery inefficiencies.

6. The battery monitoring system of claim 5, wherein the alternate route is an efficiency route.

7. The battery monitoring system of claim 1, wherein the battery monitoring application is configured to predict a battery efficiency for the vehicle based on the weather data.

8. A battery monitoring system, comprising:
a vehicle processor storing battery data; and
a user device communicatively coupled with the vehicle processor and including data processing hardware storing a weather application, a navigation application, and a battery monitoring application configured to receive the battery data from the vehicle processor and weather data from the weather application, the battery monitoring application configured to present a user with battery efficiency options based on the battery data and the weather data.

9. The battery monitoring system of claim 8, wherein the battery efficiency options include one or more of an alternate travel time, an alternate route, and efficient driving patterns.

10. The battery monitoring system of claim 9, wherein the efficient driving patterns include recommendations for increased battery efficiency.

11. The battery monitoring system of claim 9, wherein the battery monitoring application is configured to determine the alternate route and the alternate travel time in response to navigation data from the navigation application.

12. The battery monitoring system of claim 11, wherein the battery monitoring application is configured to determine the battery efficiency options based on the battery data, the weather data, and the navigation data.

13. The battery monitoring system of claim 12, wherein the navigation data includes a route and traffic data, the battery monitoring application being configured to determine an efficiency of the route based on at least one of the weather data and the traffic data.

14. The battery monitoring system of claim 13, further including a server configured to identify third-party processors along the route and configured to transmit third-party efficiency data to the battery monitoring application.

15. A vehicle battery monitoring system, comprising:
a vehicle processor storing battery data;
a user device communicatively coupled with the vehicle processor and including data processing hardware storing a navigation application and a battery monitoring application configured to receive the battery data from the vehicle processor and navigation data from the navigation application; and
a server communicatively coupled to the user device and configured to receive the navigation data and to monitor battery efficiency data from one or more third-party processors based on the navigation data, the server being configured to transmit the battery efficiency data to the user device and the battery monitoring application being configured to present a user with revised efficiency options based on the battery data and the battery efficiency data.

16. The vehicle battery monitoring system of claim 15, wherein the user device includes a weather application including weather data, the battery monitoring application being configured to determine a battery efficiency option in response to the weather data.

17. The vehicle battery monitoring system of claim 16, wherein the battery efficiency option includes an alternate departure time.

18. The vehicle battery monitoring system of claim 15, wherein the battery monitoring application is configured to identify a first route and a second route based on the navigation data and the battery data.

19. The vehicle battery monitoring system of claim 18, wherein the battery monitoring application is configured to compare the battery efficiency data from the server with each of the first route and the second route.

20. The vehicle battery monitoring system of claim 19, wherein the battery monitoring application is configured to present one of the first route and the second route as an efficiency route in response to the battery efficiency data.
